(19) United States
(12) Patent Application Publication
(10) Pub. No.: US 2008/0217695 A1
(43) Pub. Date: Sep. 11, 2008

(54) Heterogeneous Semiconductor Substrate

(75) Inventor: Petar Atanackovic, Palo Alto, CA (US)

Correspondence Address: DEMONT & BREYER, LLC, 100 COMMONS WAY, Ste. 250, HOLMDEL, NJ, 07733, US

(73) Assignee: TRANSLUCENT PHOTONICS, INC., Palo Alto, CA (US)

(21) Appl. No.: 11/682,078

(22) Filed: Mar. 5, 2007

(51) Int. Cl. H01L 27/092; H01L 21/8238; H01L 29/04

(52) U.S. Cl. 257/369; 257/77; 438/198; 257/E21.633; 257/E27.064; 257/E29.004

(57) ABSTRACT

A substrate comprising a first region of a first semiconductor and a second region of second semiconductor, wherein the first semiconductor and the second semiconductor are different, is disclosed. The substrate is particularly supportive of p-channel MOSFETs and n-channel MOSFETs having carrier mobility that is closer than in substrates comprising a single semiconductor.

### CROSS REFERENCE TO RELATED APPLICATIONS

The underlying concepts, but not necessarily the language, of the following cases are incorporated by reference:

(1) U.S. patent application Ser. No. 11/253,525, filed 19 Oct. 2005; and

(2) U.S. patent application Ser. No. 11/254,031, filed 19 Oct. 2005.

If there are any contradictions or inconsistencies in language between this application and one or more of the cases that have been incorporated by reference that might affect the interpretation of the claims in this case, the claims in this case should be interpreted to be consistent with the language in this case.

### FIELD OF THE INVENTION

The present invention relates to integrated circuit technology in general, and, more particularly, to integrated circuit substrates.

### BACKGROUND OF THE INVENTION

A conventional Metal-Oxide-Semiconductor Field-Effect Transistor (MOSFET) has four electrical terminals: drain, source, gate, and substrate. Structurally, the gate comprises an electrically-conductive polysilicon layer (i.e., a gate conductor) that is disposed on a silicon dioxide layer (i.e., a gate dielectric). The gate dielectric electrically isolates the gate conductor from the active layer, and acts as one plate of a capacitor structure. The region of the active layer that is located directly under the gate is called the channel. Typically, the channel is doped so that it contains either negative charge carriers (electrons) or positive charge carriers (holes). The channel is bracketed by a source and a drain, which are typically doped with a charge carrier opposite to that of the channel.

When a voltage is applied to the gate terminal, an electric field is created under the gate, which drives away existing charge carriers in channel. This creates a charge carrier “depletion region” in the channel. For a gate voltage that is sufficiently high (i.e., greater than a “threshold voltage”), a carrier-type “inversion” occurs in the channel and electric current can flow between the source and drain. In other words, the MOSFET is activated by the application of a gate voltage higher than the threshold voltage. The size of a transistor and the speed at which the charge-carriers can move within its channel are major factors in determining the operating speed of a MOSFET.

The remarkable decades-long progression in the performance of state-of-the-art electronics has been enabled by steadily shrinking the size of these transistors. The desired pace of MOSFET device scaling has the gate-length (i.e., size) of transistors shrinking to less than 100 nanometers (nm). But achieving this size scale is problematic. In particular, for transistors formed using conventional bulk silicon substrates, performance begins to suffer when gate length is reduced to less than 100 nm. At this size scale, substrate effects and physical limitations associated with silicon dioxide gate dielectric material become severe. As a result, silicon-on-insulator (SOI) substrates have been developed, wherein the transistors are formed on a silicon layer (i.e., the active layer) that is electrically isolated from the substrate by a buried oxide layer. Transistors formed on the active layer exhibit lower electrical current leakage, as compared to transistors formed on bulk silicon substrates, as well as other improved performance benefits.

CMOS circuits have traditionally been fabricated on silicon substrates (or active layers) that have a substantially <100> crystal orientation. In addition to their ready availability, these substrates exhibit high electron mobility that yields fast operation for n-channel MOSFETs. Unfortunately, the use of these <100> substrates results in relatively lower operating speeds for p-channel MOSFETs. As a consequence, high-speed CMOS circuit design emphasizes the use of n-channel MOSFETs in order to improve the speed of circuit operation. This can lead to complex designs and inefficient use of available chip real-estate, which result in higher cost integrated circuits. The electronics industry has great interest, therefore, in the development of a cost-effective substrate that supports p-channel MOSFETS and n-channel MOSFETS whose charge carriers have comparable mobility.

In an n-channel MOSFET, the current flow consists primarily of charge carriers that are electrons. In a p-channel MOSFET, the current flow consists primarily of charge carriers that are holes. The operating speed of an n-channel MOSFET, therefore, is a function of the speed at which electrons can flow through its channel. Likewise, the operating speed of a p-channel MOSFET is a function of the speed at which holes can flow through its channel. Carrier mobility in the channel is highly dependent upon the type of semiconductor used for the channel material as well as its crystallinity.

It is well known that the crystal orientation of the channel material can affect carrier mobility. For example, electron mobility in silicon having a <110> crystal orientation (hereinafter, referred to as “<110> silicon”) is approximately half the electron mobility in silicon whose crystal structure has a substantially <100> crystal orientation (hereinafter, referred to as “<100> silicon”). Further, hole mobility in <110> silicon is approximately 2.5 times higher than hole mobility in <100> silicon. More balanced transistor operation can be attained, therefore, by p-channel MOSFETs fabricated on <110> silicon and n-channel MOSFETs fabricated on <100> silicon. Even better balance in transistor operation can be achieved using substrates with regions of different semiconductors (e.g., germanium and silicon, etc.) for each MOSFET type. In practice, however, it has proven difficult to produce substrates that are supportive of fabrication of MOSFETs in such a manner.

Several approaches for cost-effectively producing silicon substrates with multiple crystal orientations and/or semiconductors have been pursued in the prior-art. A first such approach relies upon wafer bonding of <abc> silicon to a <def> bulk silicon wafer, using an interfacial oxide layer between them. Wafer bonding is followed by etching to expose a surface of the <def> silicon wafer for epitaxial semiconductor growth. Epitaxial silicon is then grown in the etched cavity, with the underlying <def> bulk silicon acting as a seed for the crystal growth. Unfortunately, the difficulty of aligning the two types of silicon accurately makes this approach challenging in a manufacturing environment. In addition, since only the <abc> silicon is isolated from the bulk substrate by the oxide layer, only transistors formed in the <abc> silicon derive benefits of being formed on an SOI-like structure. As a result, circuit design for this “mixed” transistor arrangement becomes quite complex.

Another prior-art approach for providing mixed crystal orientation substrates improves upon the first approach by creating a buried oxide layer under the epitaxially-grown silicon. The buried oxide layer is formed by implanting oxygen into these regions and subsequently annealing the implanted oxygen into a buried silicon dioxide layer. This approach further increases the cost and complexity of the first approach, however, making it even more challenging to implement.

A third approach relies on direct silicon-silicon wafer bonding, wherein an <abc> silicon layer is directly bonded to a <def> silicon layer. In desired regions, silicon atoms are implanted into the <abc> silicon, which effectively destroys its crystal structure in these regions. A subsequent high-temperature anneal, however, is used to recrystalize these regions. Since they are in intimate contact with the underlying <def> silicon, the regions recrystalize with <def> crystal orientation. This approach, however, results in regions of silicon that exhibit areas of very high damage below their surface. This damage leads to degraded transistor performance due to effects from charge traps and non-uniform dopant distribution.

A heterogeneous substrate that supports the formation of improved performance MOSFETs and which mitigates some of the disadvantages of the prior-art represents a significant advance in the state-of-the-art for integrated-circuit substrate technology.

### SUMMARY OF THE INVENTION

The present invention provides substrates that comprise regions of a first single-crystal semiconductor type and a second single-crystal semiconductor type. Electron mobility is higher in the first semiconductor than the second semiconductor; therefore, the first semiconductor is more suitable for the formation of n-channel MOSFETs. Hole mobility is higher in the second semiconductor than the first semiconductor; therefore, the second semiconductor is more suitable for the formation of p-channel MOSFETs. In some embodiments, the hole mobility in the second semiconductor type is similar to the electron mobility in the first semiconductor type. As a result, transistor operation is more closely matched for p-channel and n-channel MOSFETS than can be achieved using a single-semiconductor substrate.

In the present invention, at least one of the semiconductor regions is disposed on a layer of single-phase rare-earth dielectric disposed on the substrate. As described in detail later in this specification, single-phase morphology is characterized by a single-crystal, single-domain crystalline structure. The dielectric is deposited via an epitaxy process. The morphology of the rare-earth dielectric(s) is a distinguishing feature of the compositions disclosed herein. In addition, the single-crystal morphology of semiconductors disposed on the rare-earth dielectric(s) is, in fact, is enabled by the presence of the single-phase rare-earth dielectric.

The presence of single-phase materials in the compositions disclosed herein results in high-quality dielectric/semiconductor interfaces, such as are required for high-performance devices and circuits. Furthermore, rare-earth dielectric layers that exhibit single-phase morphology, as disclosed herein, do not suffer from a limitation on thickness, as exhibited in the prior art.

In some embodiments, a first region comprises a <100> silicon active layer of an SOI substrate, and a second region comprises a <110> silicon layer disposed on a layer of erbium oxide disposed on the <100> silicon active layer. Each silicon layer has a single-crystal crystal structure, and the layer of erbium oxide has a single-phase crystal structure.

In some other embodiments, a first region comprises a <100> silicon active layer of an SOI substrate, and a second region comprises a <110> germanium layer disposed on a layer of erbium oxide disposed on the <100> silicon active layer. Each semiconductor layer has a single-crystal crystal structure, and the layer of erbium oxide has a single-phase crystal structure.

In some other embodiments, an n-channel MOSFET is formed in the first region of semiconductor and a p-channel MOSFET is formed in a second region of semiconductor.

### BRIEF DESCRIPTION OF THE DRAWINGS

FIG. 1A depicts a top view of a schematic diagram of a portion of a heterogeneous substrate in accordance with an illustrative embodiment of the present invention.

FIG. 1B depicts a cross-sectional view of a schematic diagram of a portion of a heterogeneous substrate in accordance with an illustrative embodiment of the present invention.

FIG. 2 depicts the crystal structure diagram of a unit cell of a rare-earth oxide having the formula RE₂O₃ in accordance with the illustrative embodiment of the present invention.

FIG. 3 depicts a chart of the polymorphs of rare-earth oxides versus temperature and as a function of cation radius.

FIG. 4 depicts a method for forming a heterogeneous substrate in accordance with the illustrative embodiment of the present invention.

FIG. 5 depicts a top view of a layer of rare-earth dielectric deposited onto a surface that is unsuitable for epitaxial growth of a single-phase rare-earth dielectric layer.

FIG. 6 depicts a cross-sectional view of a heterogeneous substrate comprising transistors in accordance with the illustrative embodiment of the present invention.

FIG. 7 depicts a cross-sectional view of a heterogeneous substrate in accordance with an alternative embodiment of the present invention.

FIG. 8 depicts a cross-sectional view of a heterogeneous substrate in accordance with an alternative embodiment of the present invention.

### DETAILED DESCRIPTION

The following terms are defined for use in this Specification, including the appended claims:
Layer means a substantially-uniform thickness of a material covering a surface. A layer can be either continuous or discontinuous (i.e., having gaps between regions of the material). For example, a layer can completely cover a surface, or be segmented into discrete regions, which collectively define the layer (i.e., regions formed using selective-area epitaxy).
Disposed on means “exists on” an underlying material or layer. This layer may comprise intermediate layers, such as transitional layers, necessary to ensure a suitable surface. For example, if a material is described to be “disposed on a substrate,” this can mean either (1) the material is in intimate contact with the substrate; or (2) the material is in contact with one or more transitional layers that reside on the substrate.
Single-crystal means a crystalline structure that comprises substantially only one type of unit-cell. A single-crystal layer, however, may exhibit some crystalline defects such as stacking faults, dislocations, or other commonly occurring crystalline defects.
Single-domain means a crystalline structure that comprises substantially only one structure of unit-cell and substantially only one orientation of that unit cell. In other words, a single-domain crystal is a single-crystal crystalline structure that exhibits no twinning or anti-phase domains.
Single-phase means a crystalline structure that is both single-crystal and single-domain.
Substrate means the material on which deposited layers are formed. Exemplary substrates include, without limitation: bulk silicon wafers, in which a wafer comprises a homogeneous thickness of single-crystal silicon; composite wafers, such as a silicon-on-insulator wafer that comprises a layer of silicon that is disposed on a layer of silicon dioxide that is disposed on a bulk silicon handle wafer; or any other material that serves as base layer upon which, or in which, devices are formed. Examples of such other materials that are suitable, as a function of the application, for use as substrate layers and bulk substrates include, without limitation, germanium, alumina, gallium-arsenide, indium-phosphide, silica, silicon dioxide, borosilicate glass, Pyrex, and sapphire.
Miscut Substrate means a substrate which comprises a surface crystal structure that is oriented at an angle to that associated with the crystal structure of the substrate. For example, a 6° miscut <100> silicon wafer comprises a <100> silicon wafer that has been cut at an angle to the <100> crystal orientation by 6° toward another major crystalline orientation, such as <110>. Typically, but not necessarily, the miscut will be up to about 20 degrees. Unless specifically noted, the phrase “miscut substrate” includes miscut wafers having any major crystal orientation. That is, a <111> wafer miscut toward the <011> direction, a <100> wafer miscut toward the <110> direction, and a <011> wafer miscut toward the <001> direction.
Semiconductor-on-Insulator means a composition that comprises a single-crystal semiconductor layer, a single-phase dielectric layer, and a substrate, wherein the dielectric layer is interposed between the semiconductor layer and the substrate. This structure is reminiscent of prior-art silicon-on-insulator (“SOI”) compositions, which typically include a single-crystal silicon substrate, a non-single-phase dielectric layer (e.g., amorphous silicon dioxide, etc.) and a single-crystal silicon semiconductor layer. Several important distinctions betweens prior-art SOI wafers and the inventive semiconductor-on-insulator compositions are that:
   Semiconductor-on-insulator compositions include a dielectric layer that has a single-phase morphology, whereas SOI wafers do not. In fact, the insulator layer of typical SOI wafers is not even single crystal.
   Semiconductor-on-insulator compositions include a silicon, germanium, or silicon-germanium “active” layer, whereas prior-art SOI wafers use a silicon active layer. In other words, exemplary semiconductor-on-insulator compositions in accordance with the invention include, without limitation: silicon-on-insulator, germanium-on-insulator, and silicon-germanium-on-insulator.

In some embodiments, the semiconductor-on-insulator compositions that are disclosed herein include additional layers between the semiconductor layer and the substrate.

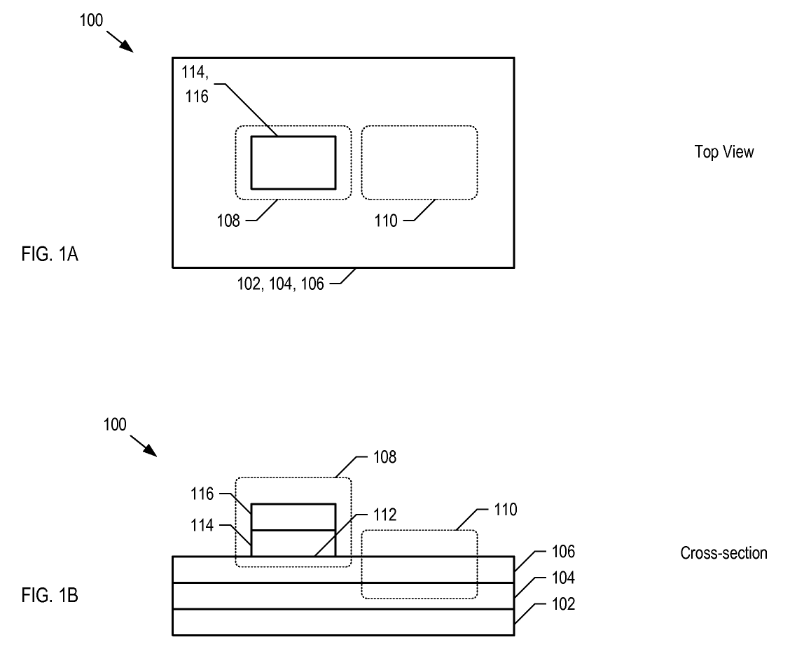

FIGS. 1A and 1B depict a top view and cross-sectional view, respectively, of a schematic diagram of a portion of a heterogeneous substrate in accordance with an illustrative embodiment of the present invention. Substrate 100 comprises handle wafer 102, buried dielectric layer 104, first semiconductor layer 106, interlayer dielectric 114, and second semiconductor layer 116.

Substrate 100 is a heterogeneous substrate that includes first region of semiconductor 108 and second region of semiconductor 110. First region 108 comprises a layer of <110> silicon. Second region 110 comprises a layer of <100> silicon. The mobility of holes, as well as electrons, differs in <110> silicon and <110> silicon. In particular, the mobility of holes in <110> silicon is higher than the mobility of holes in <100> silicon, and is, therefore, closer to that of the mobility of electrons in <100> silicon. As a result, compared to a p-channel and n-channel MOSFET formed in semiconductor having the same crystal orientation, the performance of a p-channel MOSFET formed in first region 108 can be much closer to the performance of an n-channel MOSFET formed in second region 110.

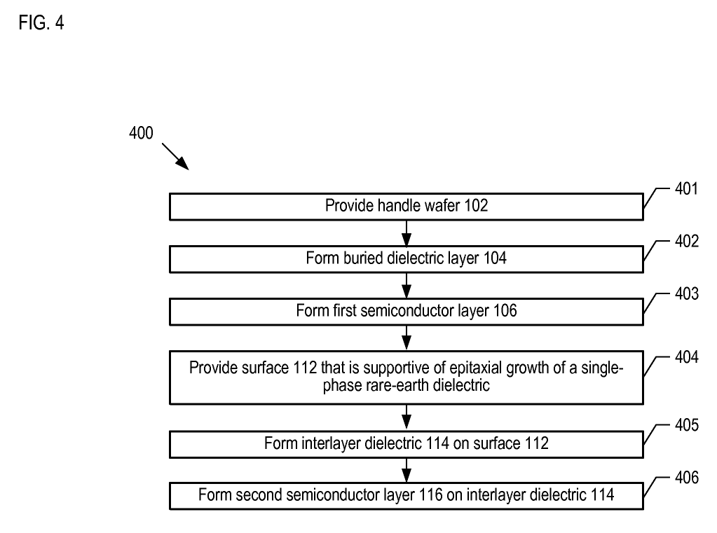

With reference to FIGS. 1 and 4, the structure of heterogeneous substrate 100 is described here in conjunction with method 400, which is suitable for the fabrication of heterogeneous substrate 100.

Method 400 begins with operation 401, in which handle wafer 102 is provided. Handle wafer 102 is a conventional silicon substrate, which is suitable for supporting the epitaxial deposition of buried dielectric layer 104.

At operation 402, buried dielectric layer 104 is formed on handle wafer 102. Buried dielectric layer 104 is a layer of erbium oxide having a thickness of approximately 10 nanometers (nm). Buried dielectric layer 104 is epitaxially-grown on and monolithically-integrated with handle wafer 102. Among any other purposes, buried dielectric layer 104 provides a high-K dielectric layer that electrically isolates first semiconductor layer 106 from handle wafer 102. Although in the illustrative embodiment buried dielectric layer 104 comprises erbium oxide, it will be clear to those skilled in the art, after reading this specification, how to make and use alternative embodiments of the present invention wherein buried dielectric layer 104 comprises a different rare-earth dielectric. Additional materials suitable for use as buried dielectric layer 104 include, without limitation:
i. other rare-earth oxides, such as oxides of ytterbium, dysprosium, holmium, thulium, and lutetium; or
ii. rare-earth nitrides, such as nitrides of erbium, ytterbium, dysprosium, holmium, thulium, and lutetium; or
iii. rare-earth phosphides, such as phosphides of erbium, ytterbium, dysprosium, holmium, thulium, and lutetium; or
iv. rare-earth oxynitrides, such as oxynitrides of erbium, ytterbium, dysprosium, holmium, thulium, and lutetium; or
v. rare-earth oxyphosphides, such as oxyphosphides of erbium, ytterbium, dysprosium, holmium, thulium, and lutetium; or
vi. any combination of i, ii, iii, iv, and v.

The thickness of dielectric layer 104 is typically in the range of 0.5 to 5000 nm. More typically, the thickness of dielectric layer 104 is in the range of 1 to 10 nm or 10 to 100 nm.

At operation 403, first semiconductor layer 106 is formed on buried dielectric layer 104. First semiconductor layer 106 is a layer of single-crystal silicon that has a thickness of 4 nm. First semiconductor layer 106 is epitaxially-grown on and monolithically-integrated with buried dielectric layer 104. First semiconductor layer 106 is suitable for formation of high-performance integrated circuits. Although the illustrative embodiment comprises first semiconductor layer 106 that is silicon, it will be clear to those skilled in the art, after reading this specification, how to make and use alternative embodiments of the present invention wherein first semiconductor layer 106 comprises:
i. silicon carbide; or
ii. germanium; or
iii. silicon-germanium; or
iv. any combination of i, ii, iii, and silicon.

In some additional embodiments, first semiconductor layer 106 is a compound semiconductor, such as gallium arsenide, indium phosphide, and alloys of gallium arsenide and indium phosphide.

The crystal structure of first semiconductor layer 106 is substantially that of <100> silicon. In some alternative embodiments of the present invention, the crystal structure of first semiconductor layer 106 is substantially that of miscut <100> silicon, wherein it has a crystal orientation that is aligned at an angle to the <100> crystal orientation toward the <110> crystal orientation, and wherein said angle is within the range of 0 degrees to 20 degrees. In some alternative embodiments, this angle is approximately six (6) degrees.

Handle wafer 102, buried dielectric layer 104, and first semiconductor layer 106 together compose a substrate that is analogous to a silicon-on-insulator (SOI) substrate as is known in the prior-art. In some embodiments of the present invention, a conventional SOI substrate is used instead of handle wafer 102 and layers 104 and 106. A key consideration for any composition in accordance with the present invention is that it must enable the formation of single-phase rare-earth dielectric layer 114.

At operation 404, surface 112 is provided. Surface 112 is that of a miscut <100> silicon surface, which is supportive of epitaxial growth of a single-phase rare-earth dielectric. Surface 112 is miscut so as to have a crystal orientation that is aligned at approximately six (6) degrees to the <100> crystal orientation toward the <110> crystal orientation. Although this angle is approximately six degrees in the illustrative embodiment, it will be clear to those skilled in the art, after reading this specification, how to make and use alternative embodiments of the present invention wherein this angle is any angle within the range of approximately 0 degrees to approximately 20 degrees.

Surface 112 is formed within region 108 by sacrificial resist etching. In sacrificial resist etching, a photoresist mask having a tapered thickness structure is formed over surface 112. The tapered structure is transferred into surface 112 by means of a reactive ion etch with appropriate chemistry. It will be clear to those skilled in the art, after reading this specification, how to provide surface 112 using sacrificial resist etching or any other suitable technique.

At operation 405, interlayer dielectric 114 is formed on surface 112. Interlayer dielectric 114 is a layer of erbium oxide having a thickness of approximately 10 nm. Among any other purposes, interlayer dielectric 114 provides a high-K dielectric layer that electrically isolates second semiconductor layer 116 from first semiconductor layer 106, thus interlayer dielectric 114 is analogous to buried dielectric layer 104. As such, interlayer dielectric 114 can comprise any of the materials and have any thickness suitable for buried dielectric layer 104. Interlayer dielectric 114 is epitaxially-grown on and monolithically-integrated with first semiconductor layer 106, using selective area growth techniques. In some alternative embodiments, interlayer dielectric 114 is epitaxially grown on the entire surface of first semiconductor layer 106 and patterned using conventional photolithography and etching techniques.

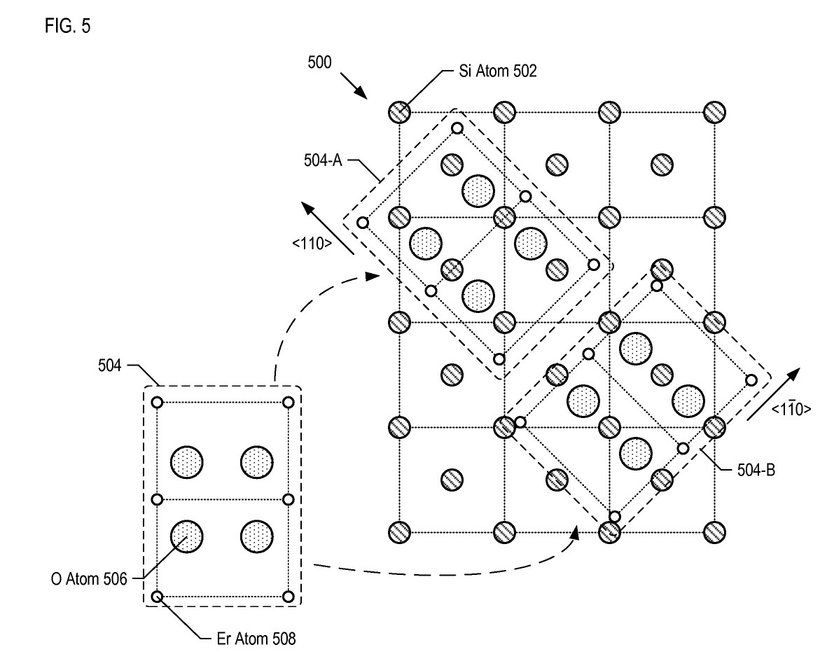

Interlayer dielectric 114 has a substantially <110> crystal structure. This crystal structure is enabled by virtue of the fact that interlayer dielectric 114 is epitaxially deposited on a miscut <100> surface. Erbium oxide is representative of a class of rare-earth dielectrics for which a miscut <100> surface acts as a template that orients the rare-earth dielectric in a specific crystalline orientation. The template behavior of surface 112 is discussed in more detail below and with respect to FIG. 5.

At operation 406, second semiconductor layer 116 is formed on interlayer dielectric 114. Second semiconductor layer 116 is a layer of single-crystal silicon having a thickness of approximately 4 nm. Second semiconductor layer 106 is epitaxially grown on and monolithically-integrated with interlayer dielectric 104. Second semiconductor layer 116 retains the crystal structure of underlying interlayer dielectric 114; therefore, semiconductor layer 116 has a substantially <110> crystal structure. Second semiconductor layer 116 is suitable for formation of high-performance integrated circuit devices. Although in the illustrative embodiment second semiconductor layer 116 is formed using selective-area epitaxial deposition, it will be clear to those skilled in the art, after reading this specification, how to make and use alternative embodiments of the present invention wherein second semiconductor layer 116 is formed using full-surface deposition followed by conventional patterning and etching operations.

Although the illustrative embodiment comprises second semiconductor layer 116 that is silicon, it will be clear to those skilled in the art, after reading this specification, how to make and use alternative embodiments of the present invention wherein second semiconductor layer 116 comprises:
i. silicon carbide; or
ii. germanium; or
iii. silicon-germanium; or
iv. any combination of i, ii, iii, and silicon.

In some alternative embodiments, surface 112 is provided by etching into the depth of first semiconductor layer 106. In some embodiments, interlayer dielectric 114 and second semiconductor layer 116 are formed in a well etched into first semiconductor layer 106, such that the top surface of substrate 100 is substantially planar.

### Crystal Structure of Rare-Earth Dielectrics

Charge carrier mobility in a single-crystal layer is higher than in a non-single crystal active layer. In addition, epitaxial deposition of a single-crystal semiconductor layer on a non-single-crystal dielectric layer would be difficult at best.

Epitaxial growth of single-phase semiconductor films is well-known to those skilled in the art. But such films are typically only grown on an underlying single-crystal semiconductor. Epitaxial growth of single-phase high-K dielectrics has been, heretofore, unknown to those skilled in the art. This section, therefore, addresses important considerations in selecting and growing single-phase, high-K, rare-earth dielectrics and single-phase semiconductors on dielectric layers.

As compared to other high-K dielectric films, single-phase rare-earth dielectric layers provide several key advantages regarding their use in integrated circuit devices. Specifically, these films enable:
a. thicker gate layers and buried dielectric layers; or
b. semiconductor-on-insulator structures with buried dielectric and active layers that do not exhibit a growth-thickness limitation; or
c. low thermionic emission of electrons across the dielectric/semiconductor interface; or
d. semiconductor/dielectric interfaces that exhibit a quality and defect density which rivals or surpasses that of silicon dioxide on silicon; or
e. fabrication of semiconductor-on-insulator structures that comprise a single-crystal semiconductor layer with a thickness of 100 nanometers or less; or
f. any combination of i, ii, iii, iv, and v.

Dielectric films that incorporate rare-earth metals are potentially a means for providing high-K dielectric films. The term “potentially” is used because there are several important caveats to the use of rare-earth metals. Specifically, the crystal structure of rare-earth dielectrics can vary significantly. And the crystal structure, in part, renders many of these otherwise acceptable rare earth dielectrics inappropriate for use in high-performance integrated circuits.

Furthermore, the crystal structure of a rare-earth dielectric can affect the quality of epitaxially-grown films that are deposited on top of the rare-earth dielectric. For example, interlayer dielectric 114 must have high interface quality and a single-Phase morphology to enable the formation of fully-depleted electrical devices in second semiconductor layer 116. Rare-earth dielectrics deposited using methods that are known in the prior art are ill-suited to the formation of fully-depleted transistor devices.

Rare-earth oxides are known to exhibit fluorite-type structures. These structures exhibit morphology differences as a function of the atomic weight of the rare-earth cation present in the oxide, among any other factors.

In particular, oxides comprising lighter rare-earths form cubic CaF₂-type crystal structure as a result of possible ionization states of +2 and/or +3 and/or +4. Oxides having this crystal structure exhibit significant net charge defect due to a multiplicity of possible oxidation states (for rare-earth oxides). This renders these rare-earth oxides inapplicable to high-performance field-effect-transistor (FET) devices. These oxides are not suitable for use in conjunction with the various embodiments of the present invention.

The layer thickness of rare-earth dielectrics is limited when grown via prior-art methods. In general, this limitation arises from lattice mismatch, internal strain, and/or electronic or structural instability of the crystal structure of the rare-earth oxides. Annealing rare-earth oxides that are formed via prior-art methods, such as hafnium oxide, in order to reduce strain undesirably results in mixed crystal phases (i.e., polycrystalline or amorphous). Layer thickness far exceeding that achieved in the prior art can be attained for rare-earth dielectrics as disclosed herein.

On the other hand, oxides formed from heavier rare-earths (e.g., RE₂O₃, etc.), exhibit a distorted CaF₂-type crystal structure which includes anion vacancies due to an ionization state of RE³⁺. The crystal structure associated with rare-earth oxides of heavier rare earths is also known as “Bixbyite.” These oxides are desirable for use as dielectric layers 104 and 114 in the compositions described herein.

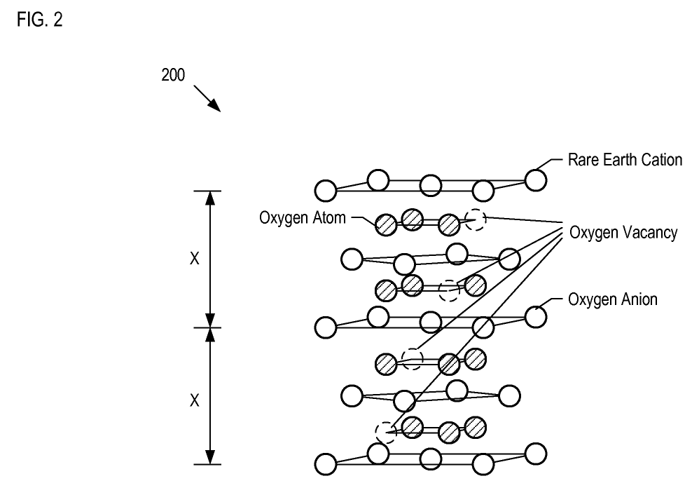

FIG. 2 depicts the crystal structure diagram of a unit cell of a rare-earth oxide having the formula RE₂O₃ in accordance with the illustrative embodiment of the present invention. Unit cell 200 is a unit cell of Er⁺³₂O₃. The crystal structure of unit cell 200 is an oxygen-vacancy-derived fluorite derivative (i.e., Bixbyite structure). Buried dielectric layer 106 and interlayer dielectric 114 comprise an assemblage of these unit cells. The erbium atoms in unit cell 200 are in a triply-ionized RE⁺³ ionization state.

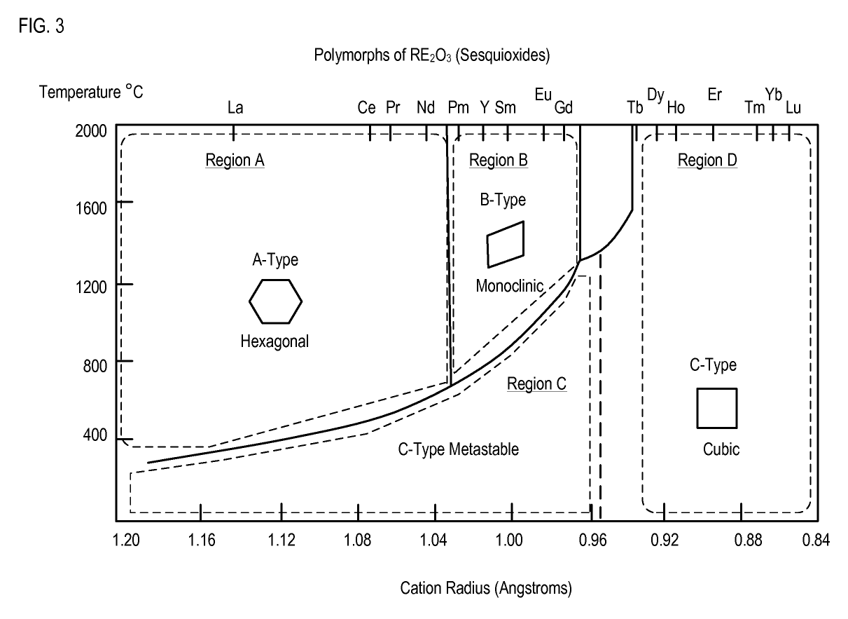

The number and position of the anion vacancies determines the crystal shape of the RE₂O₃ unit cell. The crystal shape of this cell can be engineered to provide a suitable match to the lattice constant of the underlying semiconductor substrate. Oxygen vacancies along the body diagonal and/or the face diagonal lead to a C-type cubic structure as will be discussed below and with reference to FIG. 3. For example, two anion vacancies per fluorite unit cell causes the unit cell of Er³⁺₂O₃ to increase to nearly twice the unit cell size of Si. This, in turn, enables low-strain, single-phase Er³⁺₂O₃ to be epitaxially grown directly on a silicon substrate.

Furthermore, the number and position of the anion vacancies can be engineered to induce a desired strain (tensile or compressive) in the dielectric layer and/or overgrown layers. For example, in some embodiments, strain in the semiconductor layer is desired in order to affect charge carrier mobility.

Each fluorite unit cell has two oxygen vacancies, which lie along the body diagonal as shown. The presence of these two oxygen vacancies causes the Er³⁺₂O₃ unit cell to double in size, thereby doubling its lattice constant, which provides a suitable match to the lattice constant of <100> silicon.

In some alternative embodiments, oxygen vacancies lie at the ends of the face diagonal. In some other alternative embodiments, oxygen vacancies are distributed between the ends of the face diagonal and the body diagonal.

Certain factors must be addressed to produce a composition that includes a dielectric layer comprising a single-phase rare-earth dielectric. In particular:
(1) rare-earth metals having an atomic number of 65 or less, such as cerium, promethium, or lanthanum, form cations with radii larger than 0.93 angstroms, which is unsuitable for use in embodiments of the present invention; and
(2) the growth of a polar rare-earth oxide (which comprises cations and anions) on a non-polar substrate (such as silicon or germanium) tends toward multi-domain growth due to the lack of an energetically-favorable bonding site for one of either the cations or anions of the rare-earth dielectric.

The uniformity and stability of the crystal structure of a rare-earth oxide is dependent upon the radius of the included rare-earth cation. FIG. 3 depicts a chart of the polymorphs of rare-earth oxides versus temperature and as a function of cation radius.

Regions A through C are regions of temperature and cation radius wherein the crystal structure of the polymorphs of rare-earth oxides are unstable and are not limited to a single type over all temperatures. Therefore, rare-earth oxides formed using these rare-earth elements will exhibit polycrystalline or multi-domain crystal structure. Such oxides are undesirable for use in conjunction with the compositions that are disclosed herein.

For example, the crystal structure of a rare-earth oxide comprising lanthanum, which has a cation radius of 1.14, changes as the temperature of the crystal reduces from growth temperature to room temperature. The crystal structure of such a lanthanum-oxide will change from an A-type hexagonal structure above 400° C. to a C-type metastable structure below 400° C.

Region D is the only region wherein the rare-earth oxide polymorphs are stable over the temperature range from room temperature to 2000° C. The rare-earth oxide polymorphs that exist in region C include sesquioxides that have a cation radius less than 0.93. The rare-earth elements that have cation radii less than 0.93 include dysprosium, holmium, erbium, thulium, ytterbium, and lutetium. These rare-earth elements are also characterized by an atomic number greater than or equal to 66. These rare-earth metals, therefore, will form a stable oxygen-vacancy-derived fluorite crystal structure (i.e., Bixbyite) that exhibits single-phase structure. Consequently, rare-earth metals that are suitable for use in conjunction with the illustrative embodiment include dysprosium, holmium, erbium, thulium, ytterbium, and lutetium.

Rare-earth dielectrics are typically polar. Growing polar rear-earth dielectrics on a non-polar substrate (such as silicon or germanium) usually results in multi-domain growth, which is unacceptable for use in conjunction with the present invention. In accordance with the present invention, specific techniques are employed to ensure single-phase growth of a polar layer on a non-polar surface and/or a non-polar layer on a polar surface.

In order to form a structure that is suitable for high-performance FET devices, first semiconductor layer 106 and second semiconductor layer 116 should each have a single-crystal, and preferably a single-phase, crystal structure. The optimal deposition surface for producing a single-phase active layer (e.g., silicon, germanium, silicon-carbide, or silicon-germanium) via epitaxy is non-polar, since silicon and germanium are non-polar crystals. But most rare-earth dielectrics typically comprise polar crystals. In accordance with the present invention, specific techniques are employed to ensure epitaxial growth of single-phase non-polar semiconductors on polar surfaces.

The methods employable for growing non-polar semiconductors on polar surfaces and single-phase growth of polar dielectrics on non-polar surfaces are disclosed in detail in U.S. patent application Ser. No. 11/253,525 and 11/254,031.

FIG. 5 depicts a top view of a layer of rare-earth dielectric deposited onto a surface that is unsuitable for epitaxial growth of a single-phase rare-earth dielectric layer.

Silicon surface 500 is a surface of <100> silicon, which comprises a lattice of silicon atoms 502. Unit cell 504 is a surface construction of erbium oxide unit cell 200, described above and with reference to FIG. 2. Surface construction 504 comprises four oxygen atoms 506 and six erbium atoms 508.

During epitaxial growth of a layer of erbium oxide onto silicon surface 500, oxygen atoms 506 align along the <110> crystal orientations, and thereby template the epitaxy of the erbium oxide crystal. Unfortunately, the rectangular shape of unit cell 504 leads to two equivalent axes of symmetry along each of the two <110> orientations. This can result in the epitaxial growth of a multi-phase layer of erbium oxide on a surface that is not favorable for one orientation over the other, as depicted in FIG. 5.

A miscut <100> silicon surface, however, advantageously favors one orientation of unit cell 504 over the other due to step flow. Therefore, epitaxial growth of a single-phase layer of erbium oxide can be achieved on a silicon surface that has a crystal orientation aligned at an angle to the <100> crystal orientation toward the <110> crystal orientation (e.g., surface 112 described above and with respect to FIG. 1, etc.). This angle is typically within the range of approximately 0 degrees to approximately 20 degrees, and is preferably approximately 6 degrees. The crystal orientation of such a single-phase layer of erbium oxide will be aligned to the <110> orientation. A semiconductor layer that is subsequently deposited on the erbium oxide will retain a <110> crystal orientation.

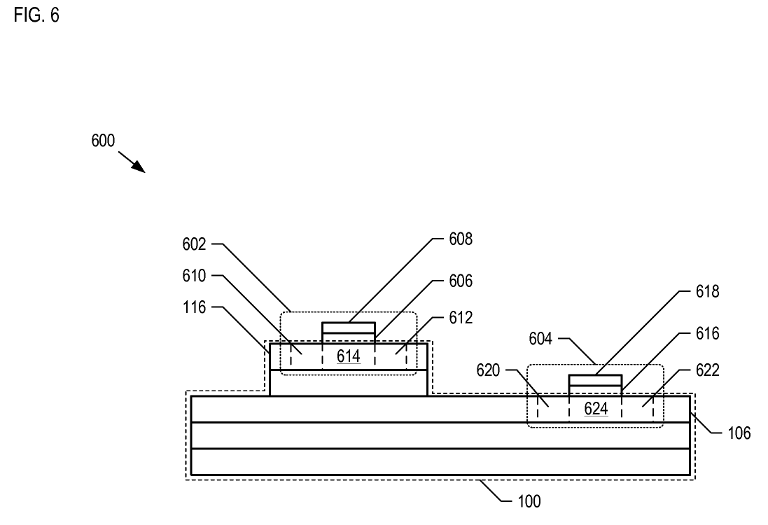

FIG. 6 depicts a cross-sectional view of a heterogeneous substrate comprising transistors in accordance with the illustrative embodiment of the present invention.

Substrate 600 comprises heterogeneous substrate 100, p-channel MOSFET 602 and n-channel MOSFET 604.

P-channel MOSFET 602 is formed on second semiconductor layer 116 in conventional fashion. It will be appreciated by those skilled in the art, that when this specification refers to a transistor formed on a layer, the term “formed on” is used to describe transistor features disposed on the top surface of the layer (e.g., the gate dielectric, gate conductor, and interconnect metallization, etc.), as well as transistor features located within the layer (e.g., the source, drain, and channel regions, etc.). P-channel MOSFET 602 comprises gate dielectric 606, gate conductor 608, source 610, drain 612, and channel region 614. By virtue of the fact that second semiconductor layer 116 has a substantially <110> crystal orientation, hole mobility within channel region 614 is enhanced as compared to hole mobility in <100> silicon.

N-channel MOSFET 604 is formed on first semiconductor layer 106 in conventional fashion. N-channel MOSFET 604 comprises gate dielectric 616, gate conductor 618, source 620, drain 622, and channel region 624.

Interconnect and contact metallization (and associated other conventional layers) on substrate 600 are not shown in FIG. 6 for clarity.

The enhanced hole mobility with channel region 614 enables transistor operation of p-channel MOSFET to be more closely matched to transistor operation of n-channel MOSFET 604. As a result, circuit operation for CMOS elements that comprise transistors such as these is improved. In alternative embodiments, wherein second semiconductor 116 comprises material exhibiting even higher hole mobility, such as germanium and the like, CMOS circuit operation is improved further.

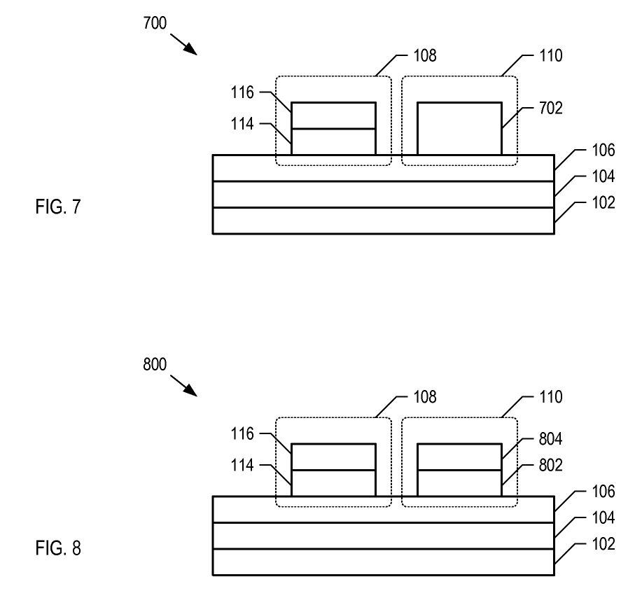

FIG. 7 depicts a cross-sectional view of a heterogeneous substrate in accordance with an alternative embodiment of the present invention.

Substrate 700 comprises handle wafer 102, buried dielectric layer 104, first semiconductor layer 106, interlayer dielectric 114, second semiconductor layer 116, and epitaxial layer 702.

Substrate 700 comprises regions 108 and 110 that are substantially co-planar. Region 110 comprises epitaxial layer 702, which is grown on the top surface of first semiconductor layer 106. Epitaxial layer 702 retains the <100> crystal orientation of first semiconductor layer 106. In some alternative embodiments, co-planarity of regions 108 and 110 is achieved by epitaxially growing epitaxial layer 702 disposed on an underlying rare-earth dielectric. In these alternative embodiments, region 110 is analogous to region 108, with the exception of the crystal orientation of epitaxial layer 702 and second semiconductor layer 116.

FIG. 8 depicts a cross-sectional view of a heterogeneous substrate in accordance with an alternative embodiment of the present invention.

Substrate 800 comprises handle wafer 102, buried dielectric layer 104, first semiconductor layer 106, interlayer dielectric 114, second semiconductor layer 116, interlayer dielectric 802, and third semiconductor layer 804.

Interlayer dielectric 802 is epitaxially deposited on and monolithically-integrated with first semiconductor layer 106. Interlayer dielectric 802 is a layer of erbium oxide having a thickness of approximately 10 nm. Among any other purposes, interlayer dielectric 802 provides a high-K dielectric layer that electrically isolates third semiconductor layer 804 from first semiconductor layer 106. Thus, interlayer dielectric 802 is analogous to interlayer dielectric 114, and comprises any of the materials suitable for interlayer dielectric 114, as described above and with respect to FIG. 1. In some embodiments, interlayer dielectric 802 is the same material as interlayer dielectric 114. In these embodiments, interlayer dielectrics 114 and 802 may be each be patterned from the same deposited rare-earth dielectric layer, deposited simultaneously by selective-area deposition, or deposited in separate operations using either selective-area deposition or conventional deposition and patterning techniques.

Third semiconductor layer 804 is a layer of single-crystal silicon having a thickness of approximately 4 nm. Third semiconductor layer 106 is epitaxially grown on and monolithically-integrated with interlayer dielectric 802. Third semiconductor layer 804 is analogous to second semiconductor layer 116, and can comprise any of the materials suitable for second semiconductor layer 116 as described above and with respect to FIG. 1. Second semiconductor layer 116 and third semiconductor layer 802 comprise different materials, however, so as to support the formation of p-channel and n-channel MOSFETs that exhibit improved comparative transistor operation, as described above and with respect to FIG. 6.

It is to be understood that the above-described embodiments are merely illustrative of the present invention and that many variations of the above-described embodiments can be devised by those skilled in the art without departing from the scope of the invention. For example, in this Specification, numerous specific details are provided in order to provide a thorough description and understanding of the illustrative embodiments of the present invention. Those skilled in the art will recognize, however, that the invention can be practiced without one or more of those details, or with other methods, materials, components, etc.

Furthermore, in some instances, well-known structures, materials, or operations are not shown or described in detail to avoid obscuring aspects of the illustrative embodiments. It is understood that the various embodiments shown in the Figures are illustrative, and are not necessarily drawn to scale. Reference throughout the specification to “one embodiment” or “an embodiment” or “some embodiments” means that a particular feature, structure, material, or characteristic described in connection with the embodiment(s) is included in at least one embodiment of the present invention, but not necessarily all embodiments. Consequently, the appearances of the phrase “in one embodiment,” “in an embodiment,” or “in some embodiments” in various places throughout the Specification are not necessarily all referring to the same embodiment. Furthermore, the particular features, structures, materials, or characteristics can be combined in any suitable manner in one or more embodiments. It is therefore intended that such variations be included within the scope of the following claims and their equivalents.

What is claimed is:

1. A substrate comprising:
a first semiconductor, wherein said first semiconductor is characterized by a first mobility of a first charge-carrier, and wherein said first semiconductor is disposed on a first dielectric layer;
said first dielectric layer, wherein said first dielectric layer comprises a first rare-earth metal, and wherein said first dielectric layer has a substantially single-phase crystal structure; and
a second semiconductor, wherein said second semiconductor is characterized by a second mobility of said first charge-carrier.

2. The substrate of claim 1 further comprising a second dielectric layer, wherein said second dielectric layer comprises a second rare-earth metal, and wherein said second dielectric layer has a substantially single-phase crystal structure, and further wherein said second semiconductor is disposed on said second dielectric layer.

3. The substrate of claim 1 wherein said first semiconductor region is characterized by a first crystal orientation, and wherein said second semiconductor region is characterized by a second crystal orientation, and further wherein said first crystal orientation is different than said second crystal orientation.

4. The substrate of claim 3 wherein said first crystal orientation is a substantially <110> crystal orientation, and wherein said second crystal orientation is a substantially <100> crystal orientation.

5. The substrate of claim 3 wherein said first crystal orientation is a substantially <110> crystal orientation, and wherein said second crystal orientation is a substantially mis-cut <100> crystal orientation.

6. The substrate of claim 1 wherein said first semiconductor and said second semiconductor are individually selected from the group consisting of silicon, germanium, silicon-germanium, and silicon-carbide.

7. The substrate of claim 1 wherein said first dielectric layer comprises at least one of a rare-earth oxide, a rare-earth oxynitride, a rare-earth nitride, a rare-earth oxyphosphide, and a rare-earth phosphide.

8. The substrate of claim 1 wherein said first rare-earth metal forms a cation having a radius less than 0.93 angstroms.

9. The substrate of claim 1 wherein said first rare-earth metal has an atomic number greater than or equal to 66.

10. The substrate of claim 1 wherein said first rare-earth metal is in a RE³⁺ ionization state.

11. The substrate of claim 1 wherein said first dielectric layer has an anion-vacancy-derived fluorite-crystal crystal structure.

12. The substrate of claim 1 further comprising:
a p-channel transistor formed in one of said first semiconductor and said second semiconductor; and
an n-channel transistor formed in the other one of said first semiconductor and said second semiconductor.

13. A substrate comprising:
a first dielectric layer disposed on said substrate, wherein said first dielectric layer comprises a first rare-earth metal, and wherein said first dielectric layer has a substantially single-phase crystal structure;
a first semiconductor disposed on said first dielectric layer, wherein said first semiconductor has a substantially single-crystal crystal structure, and wherein said first semiconductor is characterized by a first crystal orientation; and
a second semiconductor, wherein said second semiconductor layer has a substantially single-crystal crystal structure, and wherein said second semiconductor layer is characterized by a second crystal orientation, and further wherein said first crystal orientation and said second crystal orientation are different.

14. The substrate of claim 13 wherein said first dielectric layer is disposed on a surface of said substrate, and wherein said surface has a crystal orientation that is aligned at an angle to the <100> crystal orientation toward the <110> crystal orientation, and wherein said angle is within the range of 0 degrees to 20 degrees.

15. The substrate of claim 13 wherein said substrate is a mis-cut silicon wafer comprising a surface whose crystal orientation is aligned at an angle to the <100> crystal orientation toward the <110> crystal orientation, and wherein said angle is within the range of 0 degrees to 20 degrees.

16. The substrate of claim 13 wherein said first semiconductor is selected from the group consisting of silicon, germanium, silicon-germanium, and silicon-carbide.

17. The substrate of claim 16 wherein said second crystal orientation is substantially aligned to the <110> crystal orientation.

18. The substrate of claim 13 wherein said first dielectric layer comprises at least one of a rare-earth oxide, a rare-earth oxynitride, a rare-earth nitride, a rare-earth oxyphosphide, and a rare-earth phosphide.

19. The substrate of claim 13 wherein said first rare-earth metal forms a cation having a radius less than 0.93 angstroms.

20. The substrate of claim 13 wherein said first rare-earth metal has an atomic number greater than or equal to 66.

21. The substrate of claim 13 wherein said first rare-earth metal is in a RE³⁺ ionization state.

22. The substrate of claim 13 wherein said first dielectric layer has an anion-vacancy-derived fluorite-crystal crystal structure.

23. The substrate of claim 13 further comprising:
a first MOSFET, wherein said first MOSFET comprises a p-channel, and wherein said p-channel comprises at least a portion of one of said first semiconductor and said second semiconductor; and
a second MOSFET, wherein said second MOSFET comprises an n-channel, and wherein said n-channel comprises at least a portion of the other one of said first semiconductor and said second semiconductor.

24. A method comprising:
providing a substrate comprising a first semiconductor having a single-crystal crystal structure, wherein said first semiconductor is characterized by a first mobility of a first charge-carrier;
forming a first dielectric on said substrate, wherein said first dielectric comprises a rare-earth metal, and wherein said first dielectric has a single-phase crystal structure; and
forming a second semiconductor on said first dielectric, wherein said second semiconductor has a single-crystal crystal structure, and wherein said second semiconductor is characterized by a second mobility of said first charge-carrier, and further wherein said second mobility is different than said first mobility.

25. The method of claim 24 further comprising:
forming a first MOSFET, wherein the channel of said first MOSFET comprises at least a portion of said first semiconductor; and
forming a second MOSFET, wherein the channel of said second MOSFET comprises at least a portion of said second semiconductor;
wherein said first MOSFET is one of a p-channel MOSFET and an n-channel MOSFET, and wherein said second MOSFET is the other one of a p-channel MOSFET and an n-channel MOSFET.

26. The method of claim 24 further comprising providing a surface that is supportive of epitaxial deposition of said first dielectric.

27. The method of claim 26 wherein said surface is provided having a crystal orientation that is aligned at an angle to the <100> crystal orientation toward the <110> crystal orientation, and wherein said angle is within the range of 0 degrees to 20 degrees.

28. The method of claim 24 wherein said first dielectric is formed using epitaxial deposition.

29. The method of claim 24 wherein said second semiconductor is formed using epitaxial deposition.

30. The method of claim 24 wherein said semiconductor layer is deposited having a crystal orientation substantially aligned to the <110> crystal orientation.

31. The method of claim 24 wherein said first semiconductor is provided as at least one of silicon, germanium, silicon-germanium, and silicon-carbide, and wherein said second semiconductor is formed as at least one of silicon, germanium, silicon-germanium, and silicon-carbide.

32. The method of claim 24 wherein said first semiconductor is provided as silicon, and wherein said second semiconductor is formed as one of germanium, silicon-germanium, and silicon-carbide.

33. The method of claim 24 wherein said first semiconductor is provided as silicon having a crystal structure that is aligned at an angle to the <100> crystal orientation, wherein said angle is within the range of approximately 0 degrees to approximately 20 degrees, and wherein said second semiconductor is formed as silicon having a crystal structure that is substantially aligned to the <110> crystal orientation.
